(19) United States
(12) Patent Application Publication
(10) Pub. No.: US 2026/0047333 A1
(43) Pub. Date: Feb. 12, 2026

(54) PHOTODETECTORS USING SINGLE-WALLED CARBON NANOTUBES AS ABSORBING MEDIA

(71) Applicant: ELECTRONICS AND TELECOMMUNICATIONS RESEARCH INSTITUTE, Daejeon (KR)

(72) Inventors: Hyun Woo Song, Daejeon (KR); Eunsol Ko, Daejeon (KR); Dong-Ho Shin, Daejeon (KR); Won Bae Cho, Daejeon (KR)

(21) Appl. No.: 19/293,936

(22) Filed: Aug. 7, 2025

(30) Foreign Application Priority Data
Aug. 8, 2024 (KR) 10-2024-0106151

(51) Int. Cl. H10K 85/20; G01J 1/44; H10K 30/10; H10K 30/81

(52) U.S. Cl. CPC H10K 85/221; G01J 1/44; H10K 30/10; H10K 30/81; G01J 2001/4466

(57) ABSTRACT

The present invention relates to a photodetector element using carbon nanotubes (CNTs) as an absorption medium. Specifically, the present invention relates to an element that detects light at a single photon level in an absorption wavelength range of a semiconducting single-walled CNT. The present invention provides a Si semiconductor-based photodetector element that enables light detection at a single photon level in an infrared region at room temperature, which is based on the principle of injecting a charge generated by infrared absorption through a heterojunction between semiconducting single-walled CNTs and Si. The present invention is a photon measurement technology in an infrared region, and the semiconductor-based photodetector element according to the present invention can be applied to the biomedical field, the defense field, and the imaging technology field.

### CROSS-REFERENCE TO RELATED APPLICATION

This application claims priority to and the benefit of Korean Patent Application No. 10-2024-0106151, filed on Aug. 8, 2024, the disclosure of which is incorporated herein by reference in its entirety.

### BACKGROUND

### 1. Field of the Invention

The present invention relates to a photodetector element using carbon nanotubes (CNTs) as an absorption medium.

The present invention is the result of research conducted with the support of the Electronics and Telecommunications Research Institute's Internal Research and Development Programs (23YR1810 and 23RR1210, ICT National Technology Strategy Policy Support) and the Institute of Information & Communications Technology Planning & Evaluation (RS-2023-00230545, Development of Mid-Infrared Light Source-Based Remote Quantum Optical Gas Sensor System) with funding from the Korean government (Ministry of Science and ICT) in 2023.

### 2. Discussion of Related Art

Carbon nanotubes (CNTs) are known as a medium that exhibits infrared absorption properties, and they also have very high electrical conductivity. Single-walled CNTs are crystalline materials that exhibit either semiconducting or metallic properties depending on their chirality. Semiconducting single-walled CNTs have light absorption properties in the wavelength range of 800 nm to 4800 nm depending on their diameter. These mid-infrared wavelengths correspond to a range where it is difficult to fabricate photodetectors using conventional materials.

Semiconductor technologies developed for photon detection include Si-based technologies capable of measuring in the visible and near-infrared ranges (400 nm to 1100 nm). Compound semiconductors such as indium gallium arsenide (InGaAs) enable light detection in a slightly longer wavelength range (700 nm to 1600 nm) but there are limitations in detecting the mid-infrared wavelengths.

High gain photodetectors capable of single-photon detection include technologies such as photomultiplier and superconducting nanowire single-photon detectors, which are commercially available. In addition, Si-based photomultiplier technology has also been commercialized, and photon counter technology using it has matured into technologies such as a single photon avalanche diode (SPAD), Geiger-mode avalanche photo-diode (GM-APD), and multi-pixel photon counter (MPPC). However, these technologies have the limitation that they either operate only in the visible and near-infrared regions, or require extremely low temperatures, such as liquid helium cooling, which poses a significant operational disadvantage.

Meanwhile, it has been discovered that photocurrent can be obtained through a heterojunction interface between single-walled CNTs and Si, but there is still no photodetector that can operate as a photon counter at room temperature in the mid-infrared region (Patent Document 1). The applicability of photon counting technology using semiconductor sensors in the infrared range is increasing significantly. There is need for high-sensitivity photon measurement technology that can be used for detecting weak optical signals or imaging in the biomedical field.

### RELATED ART DOCUMENTS

### Patent Document

(Patent Document 1) US 2015/0228917 A1

### Non-Patent Documents

(Non-Patent Document 1) S. Moritsubo et al., “Exciton Diffusion in Air-Suspended Single-Walled Carbon Nanotubes”, Physical Review Letters, https://doi.org/10.48550/arXiv.1003.0733, 2010.
(Non-Patent Document 2) S. Cova et al., “Avalanche photodiodes and quenching circuits for single-photon detection”, Applied Optics, Vol. 35, No. 12, pp. 1956-1975, 1996.
(Non-Patent Document 3) Liu, H., Nishide, D., Tanaka, T. et al. Large-scale single-chirality separation of single-wall carbon nanotubes by simple gel chromatography. Nature Communications 2, 309. https://doi.org/10.1038/ncomms1313, 2011.

### SUMMARY OF THE INVENTION

An object of the present invention is to provide a photodetector element using carbon nanotubes (CNTs) as an absorption medium.

Specifically, an object of the present invention is to provide a semiconductor-based photodetector element that enables light detection in a mid-infrared region at room temperature at a single photon level.

The object of the present invention is not limited to the above-mentioned object, and other objects that are not mentioned will be clearly understood by those skilled in the art from the description below.

A photodetector element according to one embodiment of the present invention includes: a single-walled carbon nanotube (CNT) layer generating an electron-hole pair by incident light; and a conductive silicon crystal layer including a p-type silicon crystal layer which is bonded to a lower portion of the single-walled CNT layer and into which a charge due to the electron-hole pair is injected through either one action of diffusion and drift or a combined action thereof; and an n-type silicon crystal layer bonded to a lower portion of the p-type silicon crystal layer.

In one embodiment of the present invention, CNTs included in the single-walled CNT layer may have a diameter within a predetermined diameter range, and the single-walled CNT layer absorbs light within a wavelength range of 800 nm to 4800 nm.

In one embodiment of the present invention, the predetermined diameter range may be 0.7 nm to 4.4 nm.

In one embodiment of the present invention, the single-walled CNT layer may include a semiconducting single-walled CNT layer, which is one of an undoped semiconductor and a lightly p-type doped semiconductor.

The single-walled CNT layer may further include a p-type doped conductive carbon crystal layer disposed on top of the semiconducting single-walled CNT layer.

In one embodiment of the present invention, a heavily p-type doped carbon crystal layer (single-walled CNT layer or graphene layer) having different properties from the single-walled CNT layer may be formed on an uppermost portion of the single-walled CNT layer.

In one embodiment of the present invention, the p-type silicon crystal layer may include a first p-type silicon crystal layer and a second p-type silicon crystal layer located in the first p-type silicon crystal layer. The first p-type silicon crystal layer may be bonded to the n-type silicon crystal layer and more lightly doped than the second p-type silicon crystal layer.

In one embodiment of the present invention, the conductive silicon crystal layer may be connected to a direct voltage source that applies a reverse bias.

In one embodiment of the present invention, one end of the single-walled CNT layer and one end of the conductive silicon crystal layer may be bonded to each other, and in this case, the other end of the single-walled CNT layer and the other end of the conductive silicon crystal layer may be connected to a direct voltage source that applies a reverse bias.

In one embodiment of the present invention, the single-walled CNT layer may be formed on top of the p-type silicon crystal layer, an n+ silicon crystal layer more heavily doped than the n-type silicon crystal layer may be formed under the n-type silicon crystal layer, a cathode may be attached to the n+ silicon crystal layer, the cathode may be connected to a positive electrode of the direct voltage source, a metal electrode may be attached to the single-walled CNT layer, and the metal electrode may be connected to a negative electrode of the direct voltage source.

In one embodiment of the present invention, an n+ silicon crystal layer more heavily doped than the n-type silicon crystal layer may be formed on a lowermost portion of the n-type silicon crystal layer. In addition, a p+ silicon crystal layer more heavily doped than the p-type silicon crystal layer may be formed on an uppermost portion in a part of the p-type silicon crystal layer. A cathode may be attached to the n+ silicon crystal layer, the cathode may be connected to a positive electrode of the direct voltage source, a metal electrode may be attached to the p+ silicon crystal layer, and the metal electrode may be connected to a negative electrode of the direct voltage source.

In one embodiment of the present invention, the heavily p-type doped carbon crystal layer (single-walled CNT layer or graphene layer) may be transparent in an infrared region, have good electrical conductivity, and may be electrically connected to the metal electrode.

In one embodiment of the present invention, a quenching resistor may be further included and connected between the metal electrode and an anode.

In one embodiment of the present invention, the quenching resistor may be serially connected to the single-walled CNT layer.

In one embodiment of the present invention, the single-walled CNT layer may have a thickness smaller than a diffusion length of the electron-hole pair therein.

In one embodiment of the present invention, a one-dimensional structure of the CNTs included in the single-walled CNT layer may include a component perpendicular to the conductive silicon crystal layer.

In one embodiment of the present invention, the single-walled CNT layer may form a heterojunction with the conductive silicon crystal layer through a tip of the one-dimensional structure.

In one embodiment of the present invention, the photodetector element operates through the anode connected to a negative electrode of a direct voltage source, the quenching resistor connected thereto, the conductive carbon crystal layer connected thereto through a metal electrode, the semiconducting single-walled CNT layer connected thereto, the p-type silicon semiconductor layer heterojunctioned thereto, the n-type silicon semiconductor layer homojunctioned thereto, the cathode connected thereto, and a positive electrode of the direct voltage source connected thereto.

A multi-pixel photon counter according to one embodiment of the present invention includes: a plurality of photodetector elements that generate a current pulse by incident light and are connected in parallel; a direct voltage source applying a reverse voltage to the plurality of photodetector elements; and a current pulse measurement device measuring a height of the current pulse flowing through a circuit configured to include the plurality of photodetector elements and the direct voltage source.

The photodetector elements include: a single-walled CNT layer generating an electron-hole pair by incident light; and a conductive silicon crystal layer including a p-type silicon crystal layer which is bonded to a lower portion of the single-walled CNT layer and into which a charge due to the electron-hole pair is injected by either one action of diffusion and drift or a combined action thereof; and an n-type silicon crystal layer bonded to a lower portion of the p-type silicon crystal layer.

In one embodiment of the present invention, the plurality of photodetector elements may be arranged as in a 2-dimensional array.

In one embodiment of the present invention, CNTs included in the single-walled CNT layer may have a diameter within a predetermined diameter range, and the single-walled CNT layer absorbs light within a wavelength region of 800 nm to 4800 nm.

In one embodiment of the present invention, the single-walled CNT layer may be one of an undoped semiconductor and a lightly p-type doped semiconductor.

In one embodiment of the present invention, a heavily p-type doped carbon crystal layer (single-walled CNT layer or graphene layer) having different properties from the single-walled CNT layer may be formed on an uppermost portion of the single-walled CNT layer.

In one embodiment of the present invention, the p-type silicon crystal layer may include a first p-type silicon crystal layer and a second p-type silicon crystal layer located in the first p-type silicon crystal layer. The first p-type silicon crystal layer may be bonded to the n-type silicon crystal layer and more lightly doped than the second p-type silicon crystal layer.

In one embodiment of the present invention, the conductive silicon crystal layer may be connected to a direct voltage source that applies a reverse bias.

In one embodiment of the present invention, an n+ silicon crystal layer more heavily doped than the n-type silicon crystal layer may be formed on a lowermost portion of the n-type silicon crystal layer. In addition, a p+ silicon crystal layer more heavily doped than the p-type silicon crystal layer may be formed on an uppermost portion in a part of the p-type silicon crystal layer. A cathode may be attached to the n+ silicon crystal layer, the cathode may be connected to a positive electrode of the direct voltage source, a metal electrode may be attached to the p+ silicon crystal layer, and the metal electrode may be connected to a negative electrode of the direct voltage source.

In one embodiment of the present invention, the heavily p-type doped carbon crystal layer (single-walled CNT layer or graphene layer) may be transparent in an infrared region, have good electrical conductivity, and may be electrically connected to the metal electrode.

In one embodiment of the present invention, a quenching resistor may be further included and connected between the metal electrode and an anode.

In one embodiment of the present invention, the quenching resistor may be serially connected to the single-walled CNT layer.

In one embodiment of the present invention, a quenching resistor may be serially connected to each single-walled CNT layer included in the plurality of photodetector elements.

In one embodiment of the present invention, the single-walled CNT layer may have a thickness smaller than a diffusion length of the electron-hole pair therein.

In one embodiment of the present invention, a one-dimensional structure of the CNTs included in the single-walled CNT layer may include a component perpendicular to the conductive silicon crystal layer.

In one embodiment of the present invention, the single-walled CNT layer may form a heterojunction with the conductive silicon crystal layer through a tip of the one-dimensional structure.

In one embodiment of the present invention, the plurality of photodetector elements may be electrically separated and integrated as in a 2-dimensional array, and the plurality of photodetector elements may be integrated to be connected in parallel through electrodes to form a multiple pixel photon counter (MPPC) element.

In one embodiment of the present invention, a reverse bias may be applied to the MPPC element through a direct voltage source for a photon counting.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 shows a diagram illustrating a cross-sectional structure of a photodetector element according to one embodiment of the present invention and a cross-sectional spatial distribution of electric field intensity (cross-sectional view);

FIG. 2 shows a diagram illustrating a surface structure of a photodetector element (including a quenching resistor) according to one embodiment of the present invention (top view);

FIG. 3A shows a diagram illustrating a quenching resistor serially connected to a photodetector element according to one embodiment of the present invention;

FIG. 3B shows a diagram illustrating a current pulse of a photodetector element according to one embodiment of the present invention;

FIGS. 4A and 4B show diagrams illustrating a structure of a single-walled carbon nanotube (CNT) thin film;

FIG. 5A shows a diagram illustrating a configuration of a multi-pixel photon counter according to one embodiment of the present invention; and

FIG. 5B shows a diagram illustrating a current pulse of a multi-pixel photon counter according to one embodiment of the present invention.

### DETAILED DESCRIPTION OF EXEMPLARY EMBODIMENTS

The present invention relates to a photodetector element using carbon nanotubes (CNTs) as an absorption medium. Specifically, the present invention relates to an element that detects light at a single photon level in an absorption wavelength range of a semiconducting single-walled CNT. The present invention provides a Si semiconductor-based photodetector element that enables light detection at a single photon level in an infrared region at room temperature, which is based on the principle of injecting a charge generated by infrared absorption through a heterojunction between semiconducting single-walled CNTs and Si. The present invention is a photon measurement technology in an infrared region, and the semiconductor-based photodetector element according to the present invention can be applied to the biomedical field, the defense field, and the imaging technology field.

The advantages and features of the present invention and methods for achieving them will become apparent with reference to the embodiments described in detail below together with the accompanying drawings. However, the present invention is not limited to the embodiments disclosed below, but may be implemented in various different forms, and the present embodiments are provided only to make the disclosure of the present invention complete and to fully inform those skilled in the art of the scope of the invention, and the present invention is defined only by the scope of the claims. Meanwhile, terminology used herein is for the purpose of describing embodiments only and is not intended to limit the present invention. Singular forms used herein include plural forms, unless the context clearly indicates otherwise. “Comprise” and/or “comprising” used herein specify(ies) the presence of mentioned components, steps, operations, and/or devices do(es) not preclude the possibility of the presence or addition of one or more other components, steps, operations, and/or devices.

Although such terms as “first,” “second,” and the like may be used to describe various components, such components should not be limited by the above terms. The above terms are used only to distinguish one component from another. For example, without departing from the scope of the present invention, a first component could be named a second component, and similarly, a second component could also be named a first component.

When a component is said to be “linked” or “connected” to another component, it should be understood that the component may be directly linked or connected to the other component, but that there may be other components therebetween. On the other hand, when it is said that a component is said to be “directly linked” or “directly connected” to another component, it should be understood that there are no other components therebetween. Other expressions that describe the relationship between components, such as “between” and “immediately between” or “adjacent to” and “directly adjacent to,” should be interpreted in the same manner.

In the description of the present invention, when it is determined that the detailed description of the related art would obscure the gist of the present invention, the description thereof will be omitted.

Hereinafter, embodiments of the present invention will be described in detail with reference to the attached drawings. In order to facilitate overall understanding in describing the present invention, the same reference numerals will be used for the same means regardless of the drawing numbers.

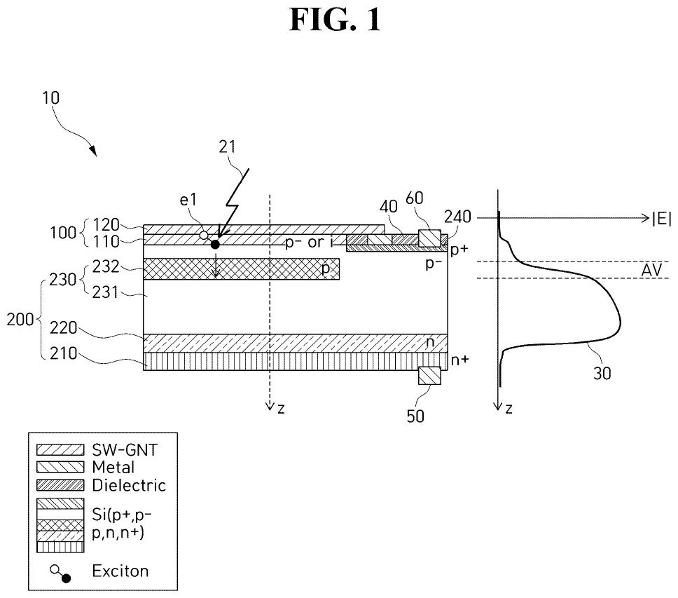

FIG. 1 shows a diagram illustrating a cross-sectional structure of a photodetector element according to one embodiment of the present invention and a cross-sectional spatial distribution of electric field intensity. A photodetector element 10 according to one embodiment of the present invention is an element capable of detecting light at a single photon level in an absorption wavelength range of a CNT. The photodetector element 10 may serve as a photon counter element for a single photon belonging to a mid-infrared wavelength band. FIG. 1 discloses a structure of a Si-based photodetector element in which a single-walled carbon nanotube layer (SW-GNT) 100 and a conductive silicon crystal layer 200 are heterojunctioned.

A photodetector element 10 according to one embodiment of the present invention includes a single-walled CNT layer 100 and a conductive silicon crystal layer 200 heterojunctioned to a lower portion of the single-walled CNT layer 100. The conductive silicon crystal layer 200 may have a structure in which a p+ silicon crystal layer 240, a p-type silicon crystal layer 230, an n-type silicon crystal layer 220, and an n+ silicon crystal layer 210 are located in this order. A cathode 50 is attached to the n+ silicon crystal layer 210, and a metal electrode 60 is attached to the p+ silicon crystal layer 240. The p-type silicon crystal layer 230 may include a first p-type silicon crystal layer 231 and a second p-type silicon crystal layer 232. The first p-type silicon crystal layer 231 may have a p-type doping concentration lower than the p-type doping concentration of the second p-type silicon crystal layer 232, and the p+ silicon crystal layer 240 may have a p-type doping concentration higher than the p-type doping concentration of the second p-type silicon crystal layer 232.

The photodetector element 10 illustrated in FIG. 1 is according to one embodiment, and the components of the photodetector element 10 according to the present invention are not limited to the embodiment illustrated in FIG. 1, and components may be added, changed, or deleted as needed. For example, the photodetector element 10 may further include a quenching resistor 70 connected to an anode 61.

As illustrated in FIG. 1, a part of the upper portion of the p-type silicon crystal layer 230 may be bonded to the single-walled CNT layer 100, and another part may be bonded to the p+ silicon crystal layer 240.

The single-walled CNT layer 100 generates an electron-hole pair (e1) by incident light 21 (photon). A semiconducting single-walled CNT layer 110 has semiconducting properties. In other words, the single-walled CNT layer 110 is a semiconducting single-walled CNT. The single-walled CNT layer 110 may be an undoped or lightly p-type doped semiconductor.

A heavily p-type doped conductive carbon crystal layer 120 (metallic single-walled CNT layer or graphene layer) having different properties from the single-walled CNT layer may be formed on an upper portion of the single-walled CNT layer 110. The conductive carbon crystal layer 120 is electrically connected to a heavily doped p+ silicon crystal layer 240.

The CNTs included in the single-walled CNT layer 110 may be formed to have a diameter within a predetermined diameter range. The single-walled CNT layer 110 may absorb light of a mid-infrared wavelength according to this diameter range.

For example, the predetermined diameter range may be 0.7 nm to 4.4 nm. In this case, the single-walled CNT layer 100 has a characteristic of absorbing light in the wavelength range of 800 nm to 4800 nm. For reference, when the semiconducting single-walled CNT has a diameter of 3.7 nm, the first transition center wavelength becomes 4200 nm.

The single-walled CNT layer 110 has a semiconducting energy band characteristic of generating an electron-hole pair e1 (exciton) by incident light 21.

Meanwhile, the electron-hole pair e1 generated inside the single-walled CNT layer 100 may move to a lower portion of the single-walled CNT layer 100 by diffusion—the diffusion length is known to be at least 610 nm (Non-Patent Document 1)—and a charge may move to the underlying silicon crystal layer 200 by drift due to an electric field 30 (or electric field cross-sectional spatial distribution) applied to the single-walled CNT layer 110. The charge moving inside the silicon crystal layer 200 undergoes significant multiplication as it passes through a high gradient region of electric fields (avalanche region, AV).

As described above, the conductive silicon crystal layer 200 includes an n-type silicon crystal layer 220 and a p-type silicon crystal layer 230. The p-type silicon crystal layer 230 is bonded to a lower portion of the single-walled CNT layer 100, and a charge by an electron-hole pair e1 is injected by diffusion or drift. The n-type silicon crystal layer 220 is bonded to a lower portion of the p-type silicon crystal layer 230.

It is known that a photocurrent can be obtained through a heterojunction at a boundary between a single-walled CNT and a silicon crystal layer (Patent Document 1). The upper layer of the photodetector element 10 that absorbs light 21 is the single-walled CNT layer 100, and the p-type silicon crystal layer 230 that is heterojunctioned with the single-walled CNT layer 100 is disposed below it.

Specifically, the p-type silicon crystal layer 230 includes a first p-type silicon crystal layer 231 and a second p-type silicon crystal layer 232. The first p-type silicon crystal layer 231 is bonded to the n-type silicon crystal layer 220 and more lightly doped than the second p-type silicon crystal layer 232.

A p+ silicon crystal layer 240 more heavily doped than the p-type silicon crystal layer 230 is formed on a part of the p-type silicon crystal layer 230. A metal electrode 60 is attached to the p+ silicon crystal layer 240. In addition, an n+ silicon crystal layer 210 more heavily doped than the n-type silicon crystal layer 220 is formed on a lower portion of the n-type silicon crystal layer 220. A cathode 50 is attached to the n+ silicon crystal layer 210.

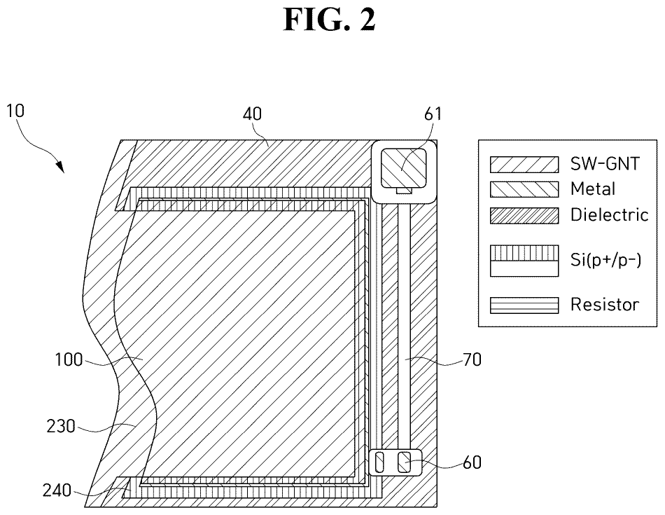

FIG. 2 shows a diagram illustrating a planar structure of a photodetector element 10 according to one embodiment of the present invention (top view). The conductive silicon crystal layer 200 is bonded to a lower portion of the single-walled CNT layer 100, the p-type silicon crystal layer 230 is bonded to a lower portion of the single-walled semiconducting CNT layer 110, and the p+ type silicon crystal layer 240 is electrically connected to a heavily p-type doped conductive carbon crystal layer 120 (single-walled CNT layer or graphene layer). The CNT layer 100 consists of a semiconducting single-walled CNT layer 110 and a conductive carbon crystal layer 120 (single-walled CNT layer or graphene layer) thereon. In addition, a quenching resistor 70 is serially connected with the conductive carbon crystal layer 120 (single-walled CNT layer or graphene layer) through a metal electrode 60 and the p+ type silicon crystal layer 240.

In the planar structure of the light detection element 10 according to one embodiment of the present invention, the semiconducting single-walled CNT layer 110 of the single-walled CNT layer 100 covers the second p-type silicon crystal layer 232 of the p-type silicon crystal layer 230 underneath it and shares most of the area.

In addition, an insulating film 40 may be used for proper electrical connection of the metal electrode 60.

The semiconductor single-walled CNT layer 110 according to one embodiment of the present invention receives light and generates an electron-hole pair e1, which immediately undergoes multiplication in the second p-type silicon crystal layer 232 positioned beneath it by diffusion or drift.

In addition, since the second p-type silicon crystal layer 232 is relatively heavily p-type doped, the photodetector element has a low breakdown voltage due to the corresponding area region.

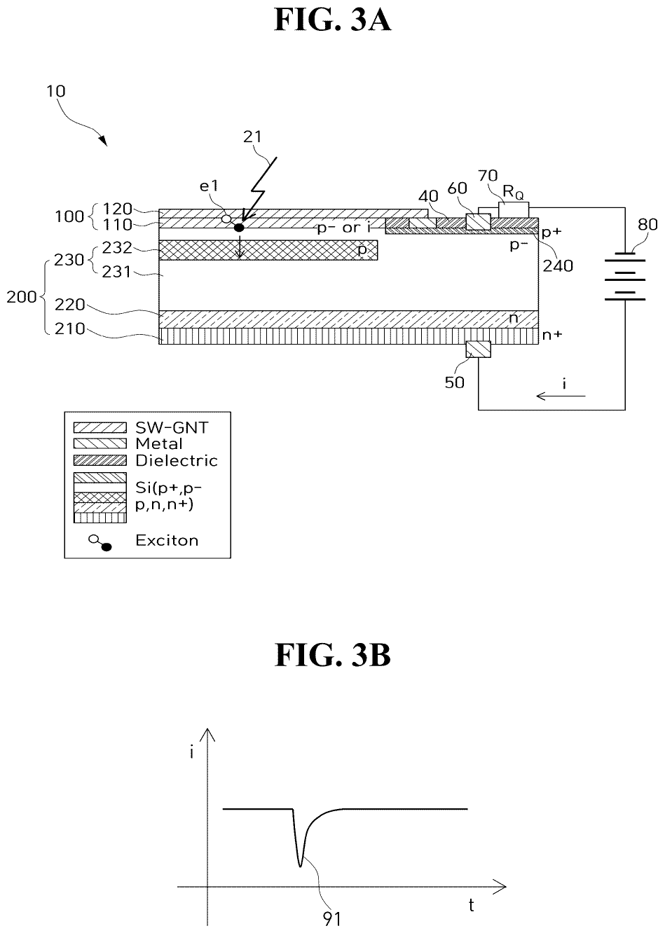

FIG. 3A shows a diagram illustrating a quenching resistor serially connected to a photodetector element according to one embodiment of the present invention, and FIG. 3B is shows a diagram illustrating a current pulse 91 of a photodetector element according to one embodiment of the present invention.

The n+ silicon crystal layer 210 is connected to a positive electrode terminal of a direct voltage source 80 through the cathode 50 attached to the n+ silicon crystal layer 210. In addition, the p+ silicon crystal layer 240 is connected to a negative electrode terminal of the direct voltage source 80 through the metal electrode 60 attached to the p+ silicon crystal layer 240. Through this structure, the direct voltage source 80 applies a reverse bias to the conductive silicon crystal layer 200. The metal electrode 60 attached to the p+ silicon crystal layer 240 is connected to a quenching resistor 70, and the quenching resistor 70 may be connected to the negative electrode terminal of the direct voltage source 80 through the anode 61.

According to one embodiment of the present invention, an electron-hole pair e1 is generated inside the single-walled CNT layer 100 that absorbs light 21 of a mid-infrared wavelength range, and a charge by dissociation of the electron-hole pair e1 passes through the heterojunction interface between the single-walled CNT layer 100 and the conductive silicon crystal layer 200 and enters the p-type silicon crystal layer 230. The electron-hole pair e1 is separated in a depletion region that is thickened due to a high reverse bias applied thereto, and the separated electron and hole are attracted to each electrode 50 and 60, thereby causing current to flow. At this time, when the magnitude of the reverse voltage corresponds to the avalanche region, which is a region near the breakdown voltage, or to the Geiger region, where a voltage exceeding the breakdown voltage to a certain extent is applied, a high current is generated even when a single charge is input. In other words, an electron separated from an electron-hole pair e1 may cause an avalanche in the second p-type silicon crystal layer 232.

For reference, the depletion layer is formed around the boundary between the n-type silicon crystal layer 220 and the p-type silicon crystal layer 230, and the depletion layer becomes thicker as the reverse voltage (bias) increases.

In order to obtain such a large current change as a current pulse and operate as a photon counter for a single photon, a quenching resistor 70 is integrated or serially connected with the photodetector element 10 having a semiconductor layer structure such as that in FIG. 1 and FIG. 3A (refer to Non-Patent Document 2).

As illustrated in FIG. 3B, when a reverse voltage higher than the breakdown voltage is applied to the photodetector element 10, an electron-hole pair e1 is generated through absorption of light 21, and the electron separated from the electron-hole pair e1 causes an avalanche in the second p-type silicon crystal layer 232, a reverse current flows. In addition, since the reverse current does not continue due to the quenching resistor 70 serially connected to the photodetector element 10, a current pulse 91 is formed as a result.

Specifically, when a reverse voltage higher than the breakdown voltage is applied, a charge flow resulting from a single photon 21 entering the photodetector element 10 may lead to a current surge. At the next moment, the voltage is partly dropped in the quenching resistor 70 serially connected to the photodetector element 10, causing the voltage applied to the semiconductor region to drop below the breakdown voltage and thereby eliminating the current surge. In other words, by serially connecting the quenching resistor 70 to the photodetector element 10, a single current pulse may be created for a single photon 21.

Meanwhile, the properties such as crystallinity and purity may vary depending on the method of forming single-walled CNTs. However, the grown single-walled CNTs are generally a mixture of metallic CNTs and semiconducting CNTs. However, since only semiconducting single-walled CNTs may stably create electron-hole pairs (excitons) through light absorption, the single-walled CNT layer 100 includes semiconducting single-walled CNTs. There is known technology for selectively extracting semiconducting single-walled CNTs from materials that are a mixture of metallic and semiconducting single-walled CNTs (Non-patent Document 3).

For the light-receiving semiconductor CNT layer 110, the single-walled CNT material is dispersed in a dispersion solution, and after forming a thin film, the dispersion solution is removed. This thin film has weak p-type semiconducting characteristics in the air even without additional doping.

A certain amount of doping is required to form the p-type doped carbon crystal layer (single-walled CNT layer or graphene layer) as an uppermost transparent electrode. The transparent electrode should be able to transmit light in the infrared region well and provide conductivity to the surface layer.

In addition, the transparent electrode should be connected to the metal electrode 60 in the vicinity in order to transmit the voltage applied to the anode 61 well and enable the generated current to flow well, and it should be electrically connected well to the light-receiving semiconductor single-walled CNT layer 110 beneath it.

CNTs are formed as a thin film with their surface exposed, and p-type doping may be performed on the surface using SOCl₂, metal halides, bis(trifluoromethanesulfonyl) imide (TFSI), tetrafluorotetracyanoquinodimethane (TFCM), NoBF₄, AuCl₃, MoO₃₋ₓ, Nafion, poly(acrylacid), and the like, and n-doping may be performed using N₂H₄, plyethylenimine, viologen derivatives, and the like. The chemicals used for doping are exposed on the surface and react in the air, and a post-process such as heat treatment may be added to ensure their stability.

In addition to the above-described chemical doping method, traditional physical doping is possible. B2H6 may be used together as a doping material during graphene synthesis to obtain a p-type doped graphene film. In addition, ammonia (NH₃) may be added during graphene synthesis to obtain an n-type doped graphene film. For n-type doping, graphene oxide may also be achieved by heat treatment in an ammonia (NH₃) atmosphere.

In the photodetector element 10 according to one embodiment of the present invention, a semiconducting single-walled CNT layer 100 capable of absorbing mid-infrared light to generate an electron-hole pair (exciton) forms a thin film in an upper portion.

In addition, in the photodetector element 10 according to one embodiment of the present invention, a light detection center wavelength may be adjusted within a wavelength range of 800 nm to 4800 nm by controlling the distribution of the diameter of the semiconducting single-walled CNTs used in the single-walled CNT layer 100.

In addition, in the photodetector element 10 according to one embodiment of the present invention, the thickness of the single-walled CNT layer 100 is smaller than the diffusion length of the electron-hole pair e1 generated inside the single-walled CNT layer 100, so that the electron-hole pairs can move across the heterojunction interface with the conductive silicon crystal layer 200 by diffusion or drift.

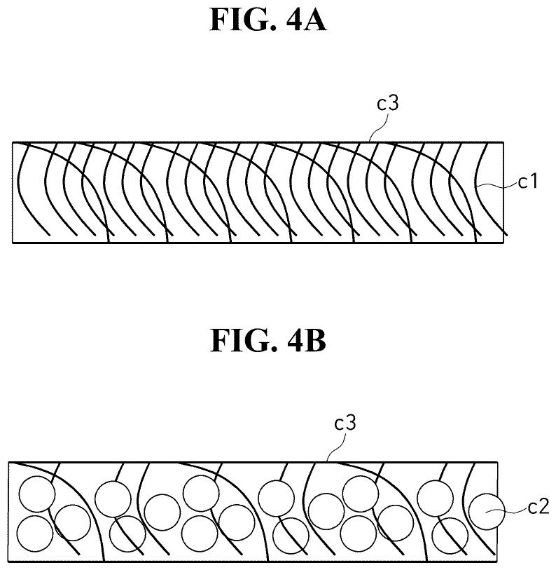

FIGS. 4A and 4B show diagrams illustrating a structure of a single-walled CNT thin film.

In the semiconductor layer structure of the photodetector element 10, the semiconductor single-walled CNT layer 110 included in the single-walled CNT layer 100 in an upper portion is characterized in that the one-dimensional structure of the single-walled CNT is formed to have a component perpendicular to the conductive silicon crystal layer 200. This one-dimensional structure c1 of the single-walled CNT layer 100 may be air-suspended (FIG. 4A) and may further include an auxiliary additive c2 (FIG. 4B). In addition, the single-walled CNT layer 100 may further include a p-type doped conductive carbon crystal layer 120 (single-walled CNT layer or graphene layer) at an uppermost portion thereof.

Meanwhile, in the one-dimensional structure of the CNT in the single-walled CNT layer 100, the crystal structures of the side wall and the tip of the CNT are different from each other. For example, the side wall may have a highly stable regular hexagonal structure (hexagonal rings), whereas the tip may have a less stable regular pentagonal structure (pentagonal rings). Through chemical treatment or thermal treatment, the single-walled CNT layer 100 forms a heterojunction at the interface when it is formed on the conductive silicon crystal layer 200 or through post-treatment after formation. In addition, it is known that the side wall of the CNT may have a heterojunction with a silicon (Si) crystal layer, but the original energy band characteristics of the semiconducting single-walled CNT may be changed (Patent Document 1). Therefore, it is preferable for the single-walled CNT layer 100 to form a heterojunction with the conductive silicon crystal layer 200 through the tip of the one-dimensional structure of the CNT.

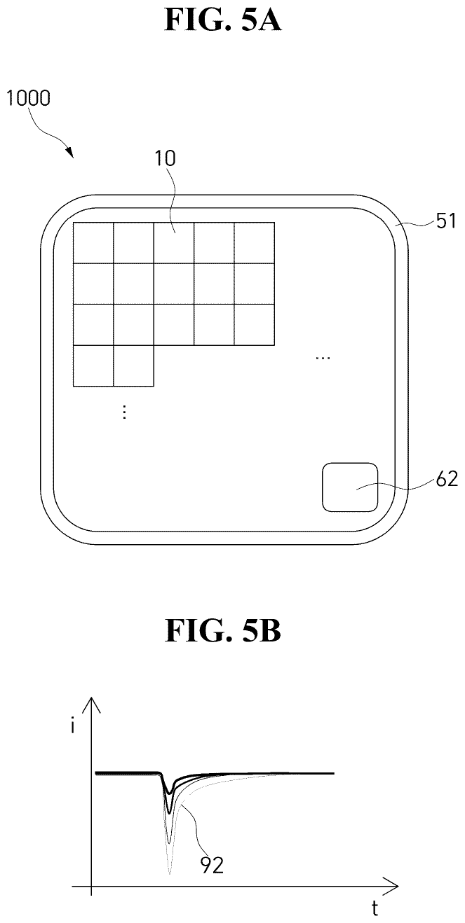

FIG. 5A shows a diagram illustrating a configuration of a multi-pixel photon counter (MPPC) according to one embodiment of the present invention, and FIG. 5B shows a diagram illustrating a current pulse 92 of an MPPC according to one embodiment of the present invention.

An MPPC according to one embodiment of the present invention may be configured to include a plurality of photodetector elements 10, a direct voltage source 80 (not shown), and a current meter 90 (not shown).

The plurality of photodetector elements 10 generate a current pulse by incident light.

The direct voltage source 80 applies a reverse bias to the plurality of photodetector elements 10, which are connected in parallel, through a cathode 51 and an anode 62. The current meter 90 measures the height of a current pulse 92 flowing through a circuit configured to include the plurality of photodetector elements 10 and the direct voltage source 80.

As described above, the photodetector element 10 may serve as a single photon counter. As illustrated in FIG. 5A, the plurality of photodetector elements 10 may be configured as a grid-shaped array. Since the plurality of photodetector elements 10 are connected in parallel, the height of the current pulse 92 merged from the plurality of photodetector elements 10 varies according to the number of photodetector elements 10 on which light is incident, as illustrated in FIG. 5B. In other words, the MPPC 1000 obtains the current pulse 92 by connecting the photodetector elements 10 in parallel.

Specifically, the MPPC 1000 may have photons to be incident simultaneously on all or part of the plurality of photodetector elements 10 in the array so that a current pulse 91 is generated from each photodetector element 10. When multiple photons are incident, the height of the current pulse 92 discretely increases according to the number of photodetector elements 10 on which the photons are incident (FIG. 5B).

In one embodiment of the present invention, the plurality of photodetectors is electrically separated from each other and integrated in a matrix form, and a number of photodetectors are integrated to be connected in parallel to each other through electrodes to form an MPPC element.

In one embodiment of the present invention, a reverse bias may be applied to the MPPC element through a direct voltage source to count photons.

An image sensor device 2000 (not shown) according to one embodiment of the present invention may be configured to integrate a plurality of photodetector elements 10 and independently drive each individual photodetector element 10 and obtain a signal from each.

The present invention provides a Si-based photodetector element having a high gain at a single photon detection level, which operates at room temperature in the near-infrared and mid-infrared (800 nm to 4800 nm) region, which is the center wavelength of light absorption of semiconducting single-walled CNTs. This photon counting performance enables detection of a minimum measurable signal in the infrared region, overcoming limitations in the related art. This corresponds to a minimum signal size that could not be measured using conventional sensors, even when the number of measurements and the number of sensors were increased.

The semiconductor-based photodetector element according to the present invention is a quantum sensor that can be utilized as a high-sensitivity photon measurement technology in the infrared region, and it can be applied to the biomedical field, the defense industry field, and the imaging industry field.

The effects obtainable from the present invention are not limited to the above-mentioned effects, and other effects not mentioned will be clearly understood by those skilled in the art to which the present invention pertains, from the description above.

Although the present invention has been described above with reference to preferred embodiments thereof, it will be understood by those skilled in the art that various modifications and changes may be possible to the present invention without departing from the spirit and scope of the present invention described in the claims below.

### REFERENCE NUMERALS

10: Photodetector element
21: Light (or photon)
30: Electric field (or electric field cross-section spatial distribution)
40: Insulating layer
50, 51: Cathode
60: Metal electrode
61, 62: Anode
70: Quenching resistor
80: Direct voltage source
90: Current meter
91, 92: Current pulse
100: Single-walled CNT
110: Semiconducting single-walled CNT layer
120: P-type doped conductive carbon crystal layer (single-walled CNT layer or graphene layer)
200: Conductive silicon crystal layer
210: N+ silicon crystal layer
220: N-type silicon crystal layer
230: P-type silicon crystal layer
231: First p-type silicon crystal layer
232: Second p-type silicon crystal layer
240: P+ silicon Crystal layer
1000: MPPC
2000: Image sensor element
e1: Hole-electron pair
c1: Semiconducting single-walled CNT
c2: Auxiliary additive
c3: Conductive carbon crystal layer

What is claimed is:

1. A photodetector element comprising:
a single-walled carbon nanotube layer generating an electron-hole pair by incident light; and
a conductive silicon crystal layer including a p-type silicon crystal layer which is bonded to a lower portion of the single-walled carbon nanotube layer and into which a charge due to the electron-hole pair is injected through either one action of diffusion and drift or a combined action thereof; and an n-type silicon crystal layer bonded to a lower portion of the p-type silicon crystal layer.

2. The photodetector element of claim 1, wherein carbon nanotubes included in the single-walled carbon nanotube layer have a diameter within a predetermined diameter range, and the single-walled carbon nanotube layer absorbs light within a wavelength range of 800 nm to 4800 nm.

3. The photodetector element of claim 2, wherein the predetermined diameter range is 0.7 mm to 4.4 mm.

4. The photodetector element of claim 1, wherein the single-walled carbon nanotube layer includes:
a semiconducting single-walled carbon nanotube layer, which is one of an undoped semiconductor and a lightly p-type doped semiconductor; and
a p-type doped conductive carbon crystal layer disposed on top of the semiconducting single-walled carbon nanotube layer.

5. The photodetector element of claim 1, wherein the p-type silicon crystal layer includes a first p-type silicon crystal layer and a second p-type silicon crystal layer located in the first p-type silicon crystal layer, and
the first p-type silicon crystal layer is bonded to the n-type silicon crystal layer and more lightly doped than the second p-type silicon crystal layer.

6. The photodetector element of claim 1, wherein one end of the single-walled carbon nanotube layer and one end of the conductive silicon crystal layer are bonded to each other, and
the other end of the single-walled carbon nanotube layer and the other end of the conductive silicon crystal layer are connected to a direct voltage source that applies a reverse bias.

7. The photodetector element of claim 6, wherein the single-walled carbon nanotube layer is formed on top of the p-type silicon crystal layer, an n+ silicon crystal layer more heavily doped than the n-type silicon crystal layer is formed under the n-type silicon crystal layer,
a cathode is attached to the n+ silicon crystal layer, wherein the cathode is connected to a positive electrode of the direct voltage source, and
a metal electrode is attached to the single-walled carbon nanotube layer, wherein the metal electrode is connected to a negative electrode of the direct voltage source.

8. The photodetector element of claim 6, wherein a quenching resistor is serially connected to the single-walled carbon nanotube layer.

9. The photodetector element of claim 1, wherein the single-walled carbon nanotube layer has a thickness smaller than a diffusion length of the electron-hole pair therein.

10. The photodetector element of claim 1, wherein a one-dimensional structure of the carbon nanotubes included in the single-walled carbon nanotube layer includes a component perpendicular to the conductive silicon crystal layer.

11. The photodetector element of claim 10, wherein the single-walled carbon nanotube layer forms a heterojunction with the conductive silicon crystal layer through a tip of the one-dimensional structure.

12. A multi-pixel photon counter comprising:
a plurality of photodetector elements that generate a current pulse by incident light and are connected in parallel;
a direct voltage source applying a reverse bias to the plurality of photodetector elements; and
a current pulse measurement device measuring a height of the current pulse flowing through a circuit configured to include the plurality of photodetector elements and the direct voltage source;
wherein the photodetector elements include:
a single-walled carbon nanotube layer generating electron-hole pairs by incident light; and
a conductive silicon crystal layer including a p-type silicon crystal layer which is bonded to a lower portion of the single-walled carbon nanotube layer and to which a charge due to the electron-hole pair is injected through either one action of diffusion and drift or a combined action thereof; and an n-type silicon crystal layer bonded to a lower portion of the p-type silicon crystal layer.

13. The multi-pixel photon counter of claim 12, wherein the plurality of photodetector elements is arranged as in 2-dimensional array.

14. The multi-pixel photon counter of claim 12, wherein carbon nanotubes included in the single-walled carbon nanotube layer have a diameter within a predetermined diameter range, and the single-walled carbon nanotube layer absorbs light within a wavelength range of 800 nm to 4800 nm.

15. The multi-pixel photon counter of claim 12, wherein the single-walled carbon nanotube layer is one of an undoped semiconductor and a lightly p-type doped semiconductor.

16. The multi-pixel photon counter of claim 12, wherein the p-type silicon crystal layer includes a first p-type silicon crystal layer and a second p-type silicon crystal layer located in the first p-type silicon crystal layer, and
the first p-type silicon crystal layer is bonded to the n-type silicon crystal layer and more lightly doped than the second p-type silicon crystal layer.

17. The multi-pixel photon counter of claim 12, wherein a quenching resistor is serially connected to each single-walled carbon nanotube layer included in the plurality of photodetector elements.

18. The multi-pixel photon counter of claim 12, wherein the single-walled carbon nanotube layer has a thickness smaller than a diffusion length of the electron-hole pair therein.

19. The multi-pixel photon counter of claim 12, wherein a one-dimensional structure of the carbon nanotubes included in the single-walled carbon nanotube layer includes a component perpendicular to the conductive silicon crystal layer.

20. The multi-pixel photon counter of claim 19, wherein the single-walled carbon nanotube layer forms a heterojunction with the conductive silicon crystal layer through a tip of the one-dimensional structure.
